(19) United States
(12) Patent Application Publication
(10) Pub. No.: US 2024/0385524 A1
(43) Pub. Date: Nov. 21, 2024

(54) SUBSTRATE TREATING APPARATUS AND SUBSTRATE TREATING METHOD

(71) Applicant: SEMES CO., LTD., Cheonan-si (KR)

(72) Inventors: Hee Man AHN, Seoul (KR); Gyeong Won SONG, Cheonan-si (KR); Jae Seung YU, Seoul (KR); Sol AN, Suwon-si (KR); Sung Hun EOM, Hwaseong-si (KR)

(73) Assignee: SEMES CO., LTD., Cheonan-si (KR)

(21) Appl. No.: 18/664,981

(22) Filed: May 15, 2024

(30) Foreign Application Priority Data
May 16, 2023 (KR) 10-2023-0062965

(51) Int. Cl. G03F 7/16; G03F 7/00

(52) U.S. Cl. CPC G03F 7/168; G03F 7/70725; G03F 7/70733; G03F 7/70875

(57) ABSTRACT

Disclosed are an apparatus and a method for treating a substrate, and more particularly, an apparatus and a method for heat treating a substrate. The apparatus includes: a heating unit provided in the inner space, and providing a treatment space in which a heating process of the substrate is performed; a transfer plate positioned within the inner space, and movable between an inner position for loading the substrate into the treatment space or for unloading the substrate from the treatment space and an outer position provided outside the heating unit; and a gas injection unit positioned within the inner space, and for injecting atmosphere gas toward the substrate at the outer position.

### CROSS-REFERENCE TO RELATED APPLICATIONS

This application claims priority to and the benefit of Korean Patent Application No. 10-2023-0062965 filed in the Korean Intellectual Property Office on May 16, 2023 the entire contents of which are incorporated herein by reference.

### TECHNICAL FIELD

The present invention relates to an apparatus and a method for treating a substrate, and more particularly, to an apparatus and a method for heat treating a substrate.

### BACKGROUND ART

To manufacture semiconductor devices or flat panel displays, various processes are performed, including photolithography, etching, and cleaning processes. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

However, with the recent integration of semiconductor devices, micro-patterning of the resist pattern is required. To realize the micro-pattern of resist patterns, an exposure process using Extreme Ultra Violet (EUV) light has been proposed. Since the exposure process using EUV light requires resist with high resolution, high etch resistance, and high sensitivity to exposure, metal-containing resist (hereinafter referred to as “metal-containing resist”) is being used as a resist.

After the exposure process is completed, a post-exposure baking process is performed. In the heat treatment chamber of the post-exposure baking process, a heating unit and a transfer plate are provided, and the substrate is heated in the heating unit and then unloaded from the heating plate by the transfer plate. The unloaded substrate is cooled while staying on the transfer plate for a period of time. Moisture-containing gas is supplied while the substrate is heated and treated in the heating unit, and dehumidifying gas is supplied to remove moisture remaining on the substrate after the heating treatment. However, even after the dehumidifying gas is supplied, the moisture is often not sufficiently removed. In order to remove the moisture, dehumidifying gas needs to be supplied for a longer period of time, which increases the time required for the heat treatment process. Also, even when cooling is performed on the transfer plate after the heat treatment is completed, when the substrate is not sufficiently cooled and is unloaded from the heat treatment chamber in a high temperature state, defects may occur. When the substrate is left on the transfer plate for a long time to cool the substrate sufficiently, the time required for the heat treatment process increases.

### SUMMARY OF THE INVENTION

The present invention to solve the foregoing problems provides a substrate treatment apparatus and a substrate treatment method that are capable of improving heat treatment efficiency when performing a heat treatment process on a substrate.

The present invention to solve the foregoing problems also provides a substrate treatment apparatus and a substrate treatment method that suppress the occurrence of defects in a metal-containing resist after performing a photolithography process on a substrate to which a metal-containing resist is applied.

The present invention to solve the foregoing problems also provides a substrate treatment apparatus and a substrate treatment method that improve the reactivity of a metal-containing resist when a post-exposure heat treatment process is performed on the metal-containing resist.

The present invention to solve the foregoing problems also provides a substrate treatment apparatus and a substrate treatment method that are capable of reducing the time required for a heat treatment process.

The object of the present invention is not limited thereto, and other objects not mentioned will be clearly understood by those of ordinary skill in the art from the following description.

An exemplary embodiment of the present invention provides an apparatus for treating a substrate, the apparatus including: a housing providing an inner space; a heating unit provided in the inner space, and providing a treatment space in which a heating process of the substrate is performed; a transfer plate positioned within the inner space, and movable between an inner position for loading the substrate into the treatment space or for unloading the substrate from the treatment space and an outer position provided outside the heating unit; and a gas injection unit positioned within the inner space, and for injecting atmosphere gas toward the substrate at the outer position.

According to the exemplary embodiment, the gas injection unit may include a showerhead including a plurality of holes formed to discharge the atmosphere gas in a downward direction.

According to the exemplary embodiment, the atmosphere gas may include dehumidifying gas, and the gas injection unit may include a dehumidifying gas supply pipe that supplies the dehumidifying gas to the showerhead.

According to the exemplary embodiment, the gas injection unit may further include a heater provided in the showerhead.

According to the exemplary embodiment, the atmosphere gas may include humidifying gas, and the gas injection unit may include a humidifying gas supply pipe supplying the humidifying gas to the showerhead.

According to the exemplary embodiment, the gas injection unit may further include a humidity regulating unit for regulating humidity of the humidifying gas.

According to the exemplary embodiment, the apparatus may further include a controller for controlling the gas injection unit, in which the controller may control the gas injection unit so that the gas injection unit injects the dehumidifying gas toward the substrate while the substrate is waiting at the outer position, after the substrate is unloaded from the heating unit.

According to the exemplary embodiment, the apparatus may further include a controller for controlling the gas injection unit, in which the controller may control the gas injection unit so that the gas injection unit injects the humidifying gas toward the substrate while the substrate is waiting at the outer position, before the substrate is loaded into the heating unit.

According to the exemplary embodiment, the showerhead may include a first porous plate and a second porous plate, the second porous plate may be positioned above the first porous plate within the showerhead, and an opening area of a hole formed in the second porous plate may be provided to be larger than an opening area of a hole formed in the first porous plate.

According to the exemplary embodiment, the showerhead may have a plurality of first holes and a plurality of second holes, the plurality of first holes may be formed in a center region of the showerhead to provide gas in a direction perpendicular to the substrate, and the plurality of second holes may be formed in an edge region of the showerhead to supply gas in a downwardly sloping direction away from the substrate.

According to the exemplary embodiment, the outer position may be the position where the transfer plate receives the substrate from a transfer member located on the outside of the housing.

According to the exemplary embodiment, the gas injection unit may further include a driver for raising and lowering the showerhead between a standby position and a second height lower than the standby position.

According to the exemplary embodiment, the transfer plate may include: a transfer plate on which the substrate is placed; and a cooling member provided on the transfer plate to cool the substrate.

Another exemplary embodiment of the present invention provides an apparatus for treating a substrate, the apparatus including: a housing providing an inner space; a heating unit provided in the inner space, and providing a treatment space in which a bake treating process of the substrate is performed; a transfer plate positioned within the inner space, and movable between an outer position provided on an exterior side of the heating unit and an inner position for loading the substrate into the treatment space or for unloading the substrate from the treatment space within the inner space; and a gas injection unit positioned above the transfer plate located at the outer position to be opposite the transfer plate, and for injecting atmosphere gas toward a substrate supported on the transfer plate, in which the gas injection unit includes: a dehumidifying gas supply line for supplying dehumidifying gas to the showerhead; a humidifying gas supply line for supplying humidifying gas to the showerhead; and a driver for raising and lowering the showerhead between a standby position and a second height lower than the standby position, and the outer position is a position where the transfer plate receives a substrate from a transfer member located on the outside of the housing.

According to the exemplary embodiment, the apparatus may further include a controller for controlling the gas injection unit, in which the controller may control the gas injection unit so that the gas injection unit injects humidifying gas toward the substrate while the substrate is supported on the transfer plate that waits at the outer position, before the substrate is loaded into the heating unit, and so that the gas injection unit may inject dehumidifying gas toward the substrate while the substrate is supported on the transfer plate that waits at the outer position, after the substrate is unloaded from the heating unit.

Still another exemplary embodiment of the present invention provides a method of treating a substrate, the method including: delivering a substrate to a transfer plate located in an inner space of a housing; loading, by the transfer plate, the substrate into a treatment space of a heating unit disposed within the housing; heat treating, by the heating unit, the substrate; upon completion of the heat treatment of the substrate in the heating unit, unloading, by the transfer plate, the substrate from the treatment space; and delivering the substrate to the outside of the housing, and the method further includes, before the loading of the substrate into the treatment space or after the unloading the substrate from the treatment space, supplying, by a gas injection unit located above the substrate in the inner space, atmosphere gas toward the substrate.

According to the exemplary embodiment, the atmosphere gas may include humidifying gas, and the providing of the atmosphere gas may include injecting the humidifying gas prior to the loading of the substrate into the treatment space.

According to the exemplary embodiment, the atmosphere gas may include dehumidifying gas, and the supplying of the atmosphere gas may include injecting the dehumidifying gas after the unloading of the substrate from the treatment space.

According to the exemplary embodiment, the heat treating process may be a heat treating process in which the substrate is subjected to a bake process after an exposure, the photoresist provided on the substrate may include a metal, and the heat treatment process may be performed while gas containing moisture is supplied to the treatment space.

According to the exemplary embodiment, the transfer plate may be movable, within the inner space, between an inner position for loading the substrate into the treatment space or for unloading the substrate from the treatment space and an outer position further away from the heating unit than the inner position, and the substrate may be supported on the transfer plate to be cooled while being in the outer position.

According to the exemplary embodiment of the present invention, heat treatment efficiency may be improved when performing a heat treatment process on a substrate.

According to one exemplary embodiment of the present invention, it is possible to suppress the occurrence of defects in the metal-containing resist after performing a photolithography process on a substrate to which the metal-containing resist is applied.

Furthermore, when a heat treatment process is performed on the metal-containing resist after exposure, the reactivity of the metal-containing resist may be improved.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top plan view schematically illustrating a transfer robot of FIG. 3.

FIG. 6 is a top plan view schematically illustrating an example of a heat treatment chamber of FIG. 4.

FIG. 7 is a front view schematically illustrating an example of the heat treatment chamber of FIG. 4.

FIG. 8 is a cross-sectional view schematically illustrating an example of the heating unit of FIG. 6.

FIG. 9 is a cross-sectional view schematically illustrating an example of a gas injection unit of FIG. 7.

FIG. 10 is a cross-sectional view schematically illustrating an example of a liquid treating chamber of FIG. 4.

FIG. 11 is a flowchart sequentially illustrating a method of heat treating a substrate.

FIGS. 12 to 16 are diagrams sequentially illustrating a portion of the process of heat treating a substrate, respectively.

FIG. 17 is a cross-sectional view illustrating another exemplary embodiment of the gas injection unit of FIG. 10.

FIG. 18 is a cross-sectional view illustrating another exemplary embodiment of the gas injection unit of FIG. 10.

FIG. 19 is a top plan view schematically illustrating another example of the heat treatment chamber of FIG. 4.

### DETAILED DESCRIPTION

Exemplary embodiments will now be described more fully with reference to the accompanying drawings. The exemplary embodiments are provided in order to make the disclosure exhaustive and will fully convey the scope to one of ordinary skill in the art. To provide a complete understanding of exemplary embodiments of the present invention, a number of specific details are presented, such as examples of certain components, devices, and methods. It will be apparent to those skilled in the art that specific details need not be utilized and that the exemplary embodiments may be implemented in many different forms, neither of which should be construed as limiting the scope of the present invention. In some exemplary embodiments, known processes, known device structures, and known techniques are not described in detail.

The terminology used herein is intended to describe certain exemplary embodiments only and is not intended to limit the exemplary embodiments. Singular expressions, such as those used herein, or expressions where the singular is not specified, are intended to include the plural expressions unless the context clearly indicates otherwise. The terms “includes,” “comprising,” “including,” and “having,” have an open-ended meaning and are therefore intended to specify the presence of the features, configurations, integers, steps, operations, elements, and/or components mentioned and do not exclude the presence or addition of one or more other features, configurations, steps, operations, elements, components, and/or groups thereof. The method steps, processes, and operations described herein are not to be construed as necessarily being performed in the particular order in which they are discussed or described, unless the order in which they are performed is specified. In addition, additional or alternative steps may be selected.

When an element or layer is referred to as being “on,” “connected to,” “bonded to,” “attached to,” “adjacent to,” or “covering” another element or layer, the element or layer may be directly on, connected to, bonded to, attached to, adjacent to, or covering the other element or layer, or intermediate elements or layers may be present. Conversely, when an element is referred to as being “directly on,” “directly connected to,” or “directly bonded to” another element or layer, it is to be understood that no intervening elements or layers are present. Throughout the specification, the same reference numeral refers to the same element. As used in the present invention, the term “and/or” includes all combinations and sub-combinations of one or more of the enumerated items.

Although terms, such as first, second, and third, may be used to describe various elements, regions, layers, and/or sections of the present invention, it is to be understood that these elements, regions, layers, and/or sections are not to be limited by these terms. These terms are used to distinguish one element, area, layer, or section from another element, area, layer, or section only. Accordingly, the first element, first area, first floor, or first section discussed below may be referred to as the second element, second area, second floor, or second section without departing from the teachings of the exemplary embodiments.

Spatially relative terms (for example, “beneath,” “underneath,” “below,” “on,” “above,” and “on top,”) may be used for ease of description to describe the relationship of one element or feature to another element(s) or feature(s) as illustrated in the drawings. It is to be understood that spatially relative terms are intended to include not only the orientations illustrated in the drawings, but also other orientations of the apparatus in use or operation. For example, when the device in the drawing is flipped, the elements described as “underneath” or “below” other elements or features may be oriented “above” other elements or features. Thus, the term “below” above may include both up and down orientations. The apparatus may be oriented differently (rotated 90 degrees, or otherwise oriented), and the spatially relative descriptive phrases used in the present invention may be construed accordingly.

It should be understood that when the terms “same” or “equal” are used in the description of exemplary embodiments, some imprecision may exist. Therefore, when an element or value is referred to as being equal to another element or value, it should be understood that the element or value is equal to the other element or value within manufacturing or operational error (for example, ±10%).

Whenever the words “approximately” or “substantially” are used herein with respect to a figure, such figure is to be understood to include manufacturing or operating error (for example, ±10%) of the stated figure. It should also be understood that the use of the words “generally” and “substantially” in reference to geometric shapes does not require geometric shape accuracy, but latitude for shape is within the scope of the disclosure.

Unless otherwise defined, all terms used in the present invention, including technical and scientific terms, have the same meaning as commonly understood by one of ordinary skill in the art to which the exemplary embodiments belong. It is also to be understood that terms, including commonly used dictionary-defined terms, are to be interpreted to have a meaning consistent with their meaning in the context of the relevant art and are not to be construed in an idealized or overly formal sense unless expressly defined in the present invention.

In the present exemplary embodiment, a wafer will be described as an example of an object to be treated. However, the technical spirit of the present invention may be applied to devices used for other types of substrate treatment, in addition to wafers.

The apparatus of the present exemplary embodiment is used to perform a photolithography process on a substrate, such as a semiconductor wafer or a flat panel display. In particular, the apparatus of the present exemplary embodiment may be connected to an exposure device and used to perform, on a substrate, a Post Exposure Bake (PEB) process that heats the substrate after the exposure process. However, the technical spirit of the present invention is not limited thereto and may be applied to various other kinds of processes other than pre- and/or post-PEB. For example, the various other kinds of processes may include a process before and/or after a heating process after an application process, a process before and/or after a heating process after an etching process, and a process before and/or after a heating process after a developing process.

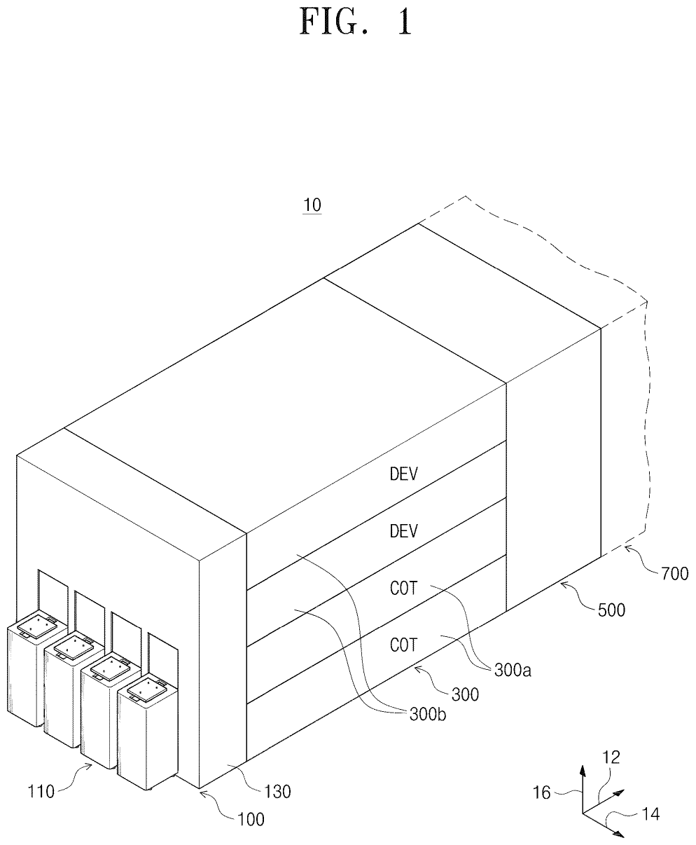

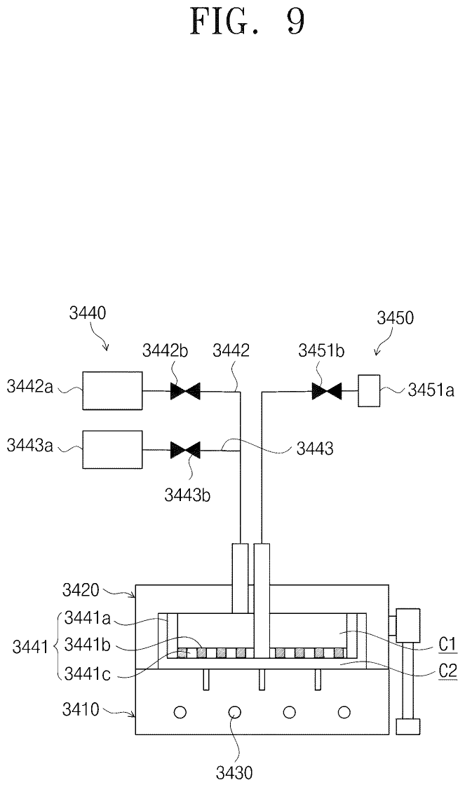

Hereinafter, exemplary embodiments of the present invention will be described with reference to FIGS. 1 to 19.

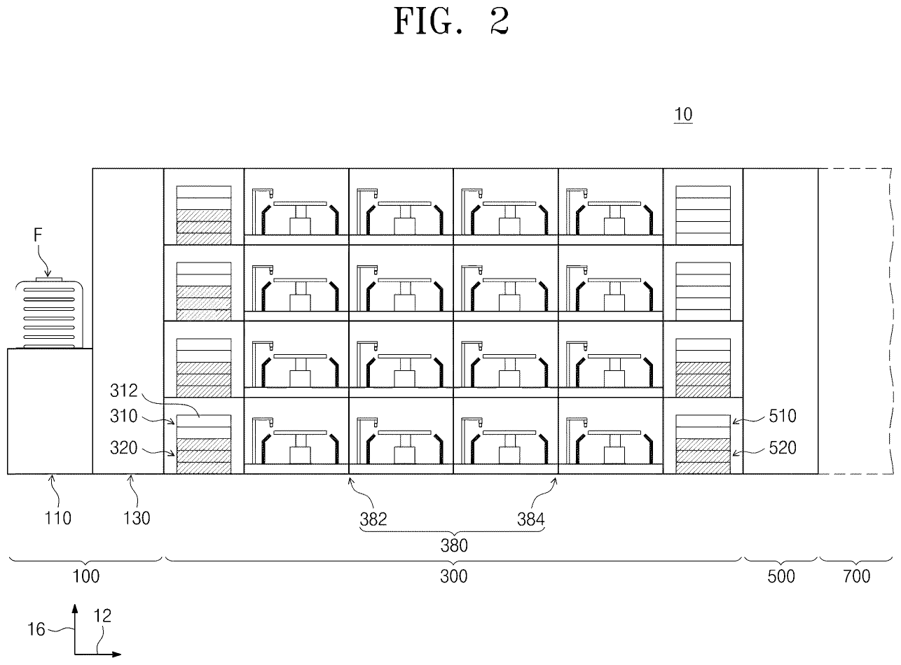

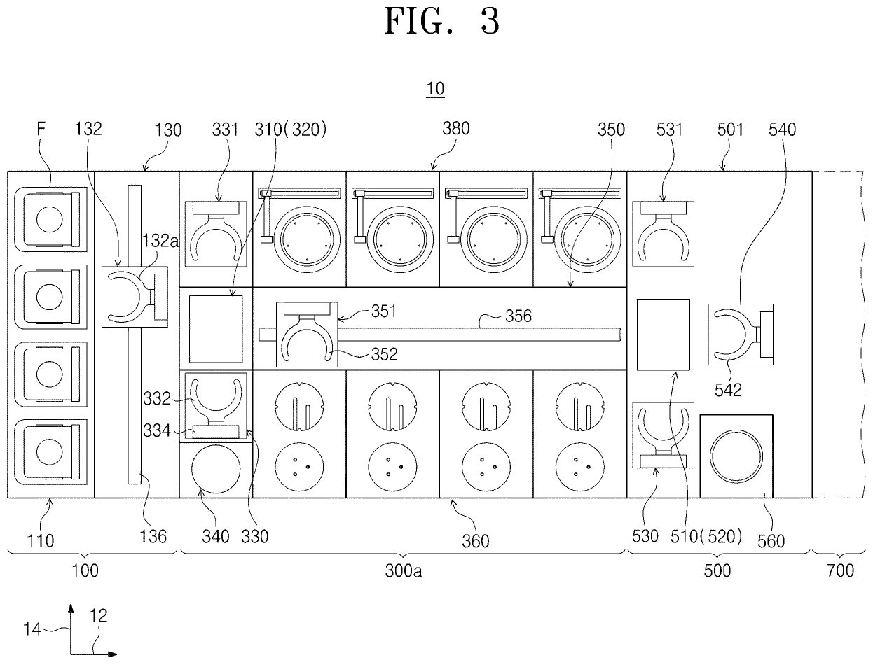

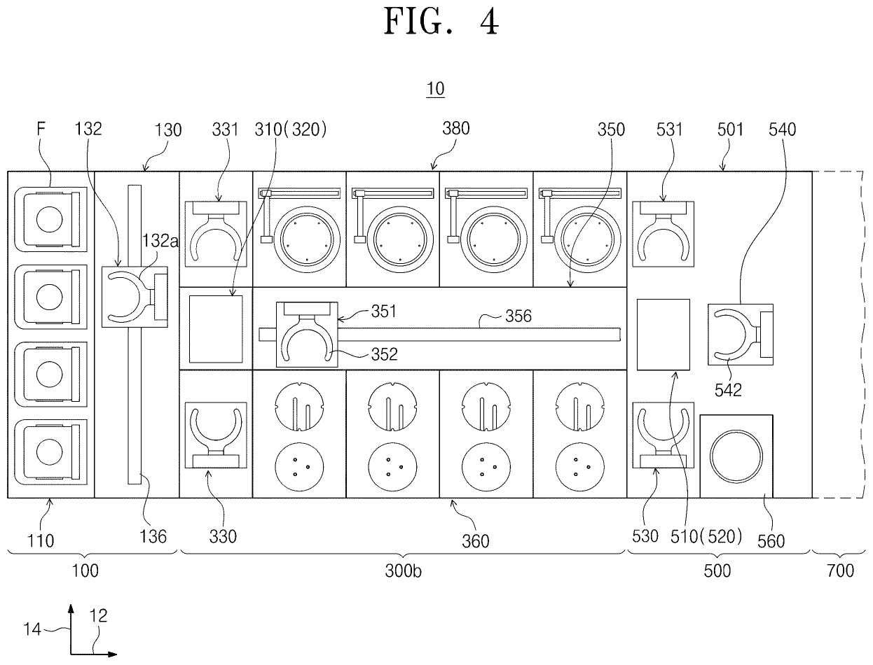

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 relative to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The treating module 300 includes a coating block 300a and a developing block 300b.

The applying block 300a performs an application process on the substrate W before the exposure process. The developing block 300b performs a development process on the substrate W after the exposure process. A plurality of applying blocks 300a is provided. The plurality of coating blocks 300a may be provided to be stacked on each other. A plurality of developing blocks 300b is provided. The plurality of developing blocks 300b may be provided to be stacked on each other. In one example, two applying blocks 300a are provided and two developing blocks 300b are provided. The plurality of applying blocks 300a may be positioned below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with identical structures that are identical to each other. A developer supplied to the substrate W in the plurality of developing blocks 300b may be the same type of liquid. Optionally, depending on the developing block 300b, the developer supplied to the substrate W may be different types of developer. For example, the process of removing light-irradiated region of the resist film on the substrate W may be performed in one of the two developing blocks 300b, and the process of removing non-irradiated region may be performed in the other of the two developing blocks 300b.

Referring to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index block 100. The hydrophobization chamber 340 and the buffer unit 310 may be sequentially disposed along the second direction 14. Further, the cooling unit 320 and the buffer unit 310 may be provided to be stacked on top of each other in a downward direction.

The buffer unit 310 includes one or a plurality of buffers 312. If a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided relative to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be positioned adjacent to the interface module 500.

A plurality of heat treating chambers 360 is provided. Some of the heat treating chambers 360 is disposed along the first direction 12. Additionally, some of the heat treating chambers 360 may be stacked along the third direction 16. The heat treating chambers 360 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side-by-side along the first direction 12. Optionally, some of the liquid treating chambers 360 may be stacked along the third direction 16.

In one example, the liquid treating chambers 380 include a front end liquid treating chamber 382 and a rear end liquid treating chamber 384. The front end liquid treating chamber 382 is disposed relatively close to the index module 100, and the rear end liquid treating chamber 384 is disposed more close to the interface module 500.

The front end liquid treating chamber 382 applies a first liquid onto the substrate W, and the rear end liquid treating chamber 384 applies a second liquid onto the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film and the second liquid may be a liquid for forming an anti-reflective film. In this case, the anti-reflective film may be formed on the substrate W on which the photoresist film is formed. Optionally, the first liquid and the second liquid may be the same type of liquid, and they may both be liquids for forming the photoresist film.

Referring to FIG. 4, the developing block 300b includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the application block 300a. When viewed from above, the buffer unit 310, the cooling unit 320, the transfer chamber 350, the heat treating chamber 360, and the liquid treating chamber 380 in the developing block 300b and the buffer unit 310, the cooling unit 320, the transfer chamber 350, the heat treating chamber 360, and the liquid treating chamber 380 in the application block 300 may be disposed in overlapping positions.

The heat treating chamber 360 performs a heating process on the substrate W. The heating process includes a post-exposure baking process performed on the substrate W after the exposure process is completed, and a hard baking process performed on the substrate W after the development process is completed.

The liquid treating chamber performs the development process by supplying a developer onto the substrate W and developing the substrate W.

In FIG. 3 or FIG. 4, the transfer chamber 350 is provided with a transfer robot 351. The transfer robot 351 transfers the substrate W between the buffer unit 310, the cooling unit 320, the heat treating chamber 360, the liquid treating chamber 380, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

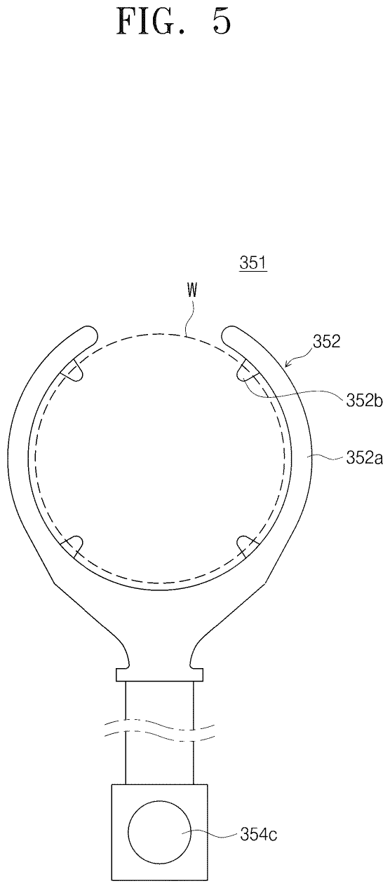

FIG. 5 is a diagram illustrating one example of the hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

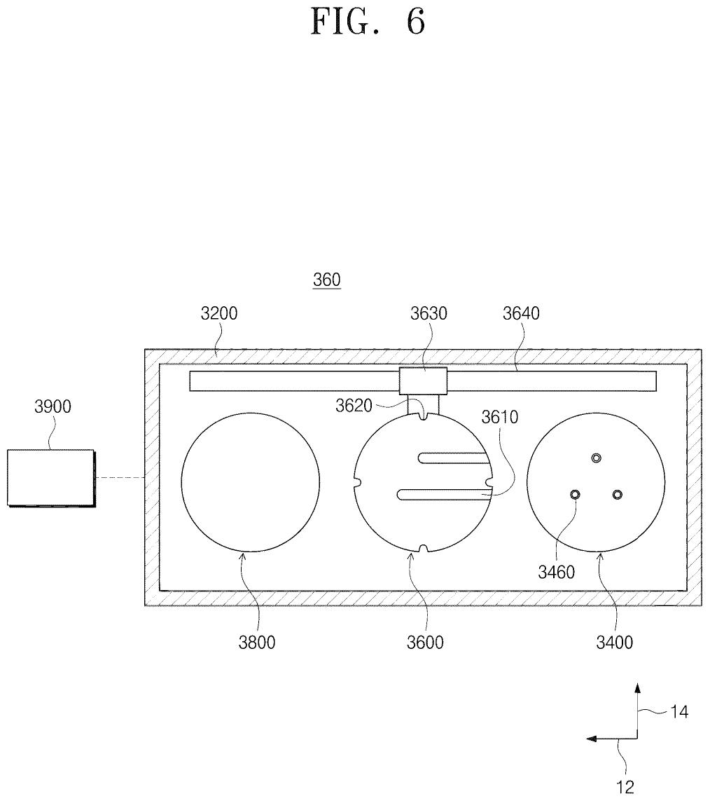

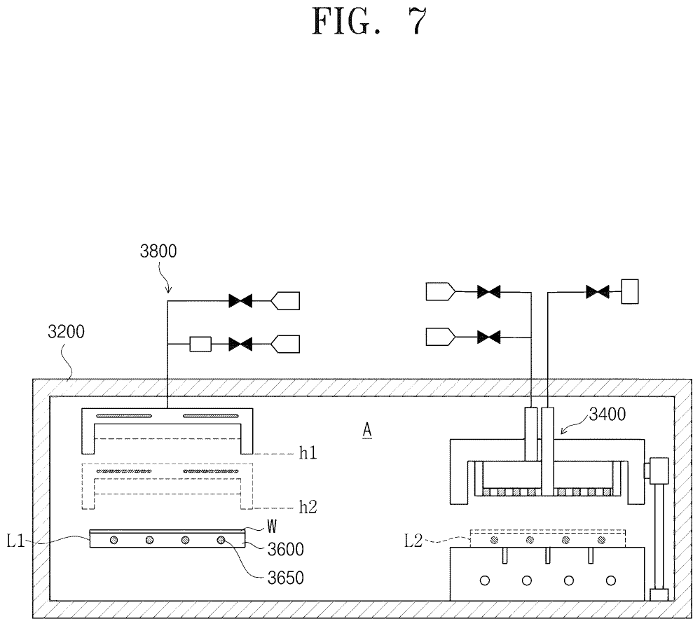

FIG. 6 is a top plan view schematically illustrating an example of a heat treatment chamber of FIG. 4, and FIG. 7 is a front view schematically illustrating an example of the heat treatment chamber of FIG. 6.

Referring to FIGS. 6 and 7, the heat treating chamber 360 includes a housing 3200, a heating unit 3400, a transfer plate 3600, and a gas injection unit 3800.

The housing 3200 is provided in the shape of a generally rectangular parallelepiped. The housing 3200 has an inner space A. An entrance port (not illustrated) through which the substrate W enters and exits is formed on a sidewall of the housing 3200. The entrance port may remain open. Optionally, a door (not illustrated) may be provided to open and close the entrance port. The heating unit 3400, the transfer plate 3600, and the gas injection unit 3800 are provided in the inner space A. In the inner space A, the transfer plate 3600 moves between an outer position L1 and an inner position L2. In the inner space A, the gas injection unit 3800 rises and falls between a standby position h1 and a gas injection position h2.

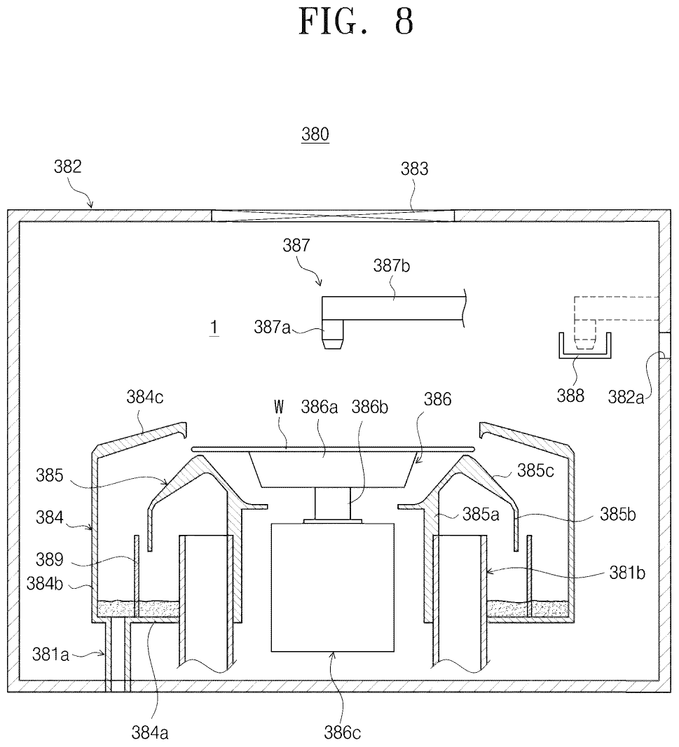

FIG. 8 is a cross-sectional view schematically illustrating an example of the heating unit.

Referring to FIG. 8, the heating unit 3400 includes a heating plate 3410, a cover 3420, a heater 3430, and a gas supply member 3440, and an exhaust member 3450. The heating plate 3410 has a substantially circular shape when viewed from above. The heating plate 3410 has a diameter larger than the substrate W. A heater 3410 is installed in the heating plate 3430. The heater 3430 may be provided as a heating wire or heating pattern that is heated by the supply of electrical power. The heating plate 3410 is provided with a lift pin 3460. The lift pin 3460 is provided to be movable in an upward and downward direction along the third direction 16. The lift pin 3460 receives the substrate W from the transfer robot 351 and places the substrate W down on the heating plate 3410, or lifts the substrate W from the heating plate 3410 and delivers the substrate W to the transfer robot 351. According to one example, three lift pins 3460 may be provided. The cover 3420 has a space with an open lower portion therein. The cover 3420 is positioned on top of the heating plate 3410 and is moved in an upward and downward direction by a driver 3470. The space formed by the cover 3420 and the heating plate 3410 according to the movement of the cover 3420 is provided as a treating space 3201 for heating the substrate W.

The gas supply member 3440 includes a shower unit 3441, a first gas supply pipe 3442, and a second gas supply pipe 3443. The shower unit 3441 is mounted inside the cover 3420. The shower unit 3410 has a sidewall 3441a and an injection plate 3441b inside the cover. The sidewall 3441a is provided in a ring shape. The injection plate 3441b is positioned at the bottom end of the sidewall 3441a. The space enclosed by the sidewall 3441a and the injection plate 3441b is provided as a gas introduction space R1. A plurality of injection holes 3441c is formed in the injection plate 3441b. The plurality of injection holes 3441c may be uniformly formed over the entire region of the injection plate 3441b. The first gas supply pipe 3442 supplies first gas to the gas introduction space C1. The first gas may be humidifying gas. The humidifying gas is gas that contains a predetermined amount of moisture. For example, the humidifying gas may be inert gas containing moisture. Optionally, the humidifying gas may be air containing moisture. For example, the humidifying gas may have a moisture content of 20 to 60%. The first gas supply pipe 3442 is connected to each of the external gas supply source 3442a and the shower unit 3441. A valve 3442b is installed on the first gas supply pipe 3442.

The second gas supply pipe 3443 supplies second gas to the gas introduction space. The second gas may be dehumidifying gas. In one example, the second gas may be low humidity air (CDA), inert gas, or nitrogen gas. The second gas supply pipe 3443 is connected to each of the external gas supply source 3443a and the shower unit 3441. A valve 3443b is installed on the second gas supply pipe 3443.

The exhaust member 3450 exhausts the atmosphere in a treating space C2. The exhaust member 3450 has an exhaust pipe 3451. In one example, the exhaust pipe 3451 may be connected to the center of the injection plate 3441b. Optionally, the exhaust member 3450 may be connected at an edge region of the injection plate 3441b. The exhaust pipe 3451 may be equipped with a pump 3451a and a valve 3451b.

Referring again to FIG. 6, the transfer plate 3600 is provided with a substantially disk-like shape and has a diameter corresponding to the substrate W. A notch 3600 is formed at the edge of the transfer plate 3620. The notch 3620 may have a shape that corresponds to the protrusion 352b formed on the hand 352 of the transfer robot 352 described above. Further, the notches 3620 are provided in a number corresponding to the protrusions 352b formed on the hand 352, and are formed at positions corresponding to the protrusions 352b. In a position in which the hand 352 and the transfer plate 3600 are aligned in an up-down direction, when the up-down position of the hand 352 and the transfer plate 3600 is changed, the substrate W is transferred between the hand 352 and the transfer plate 3600.

The transfer plate 3600 is moved between the outer position L1 and the inner position L2. The outer position L1 and the inner position L2 are spaces within the housing 3200. The outer position L1 is provided on the outer side of the heating unit 3400. The transfer plate 3600 may be the position where the substrate W is transferred to and from the transfer robot 351. The inner position L2 may be a position for the transfer plate 3600 to transfer the substrate W to and from the heating plate 3410 of the heating unit 3400.

The transfer plate 3600 may be mounted on a guide rail 3640 and may be moved along the guide rail 3640 by the driver 3630. A plurality of slit-shaped guide grooves 3600 is provided in the transfer plate 3610. The guide groove 3610 extends from the end of the transfer plate 3600 to the inside of the transfer plate 3600. The guide groove 3610 is provided along the second direction 14 in a longitudinal direction, and the guide grooves 3610 are spaced apart from each other along the first direction 12. The guide grooves 3610 prevent the transfer plate 3600 and the lift pin 3460 from interfering with each other when the transfer plate 3600 and the heating unit 3400 are handing over the substrate W.

The transfer plate 3600 may be provided with a cooling member 3650. In one example, the cooling member 3650 may be formed on the inner of the transfer plate 3600 and may be provided with a flow path through which a cooling fluid flows. The cooling flow path may be supplied with coolant to cool the substrate W.

The gas injection unit 3800 supplies atmosphere gas to the substrate W at the outer position L1.

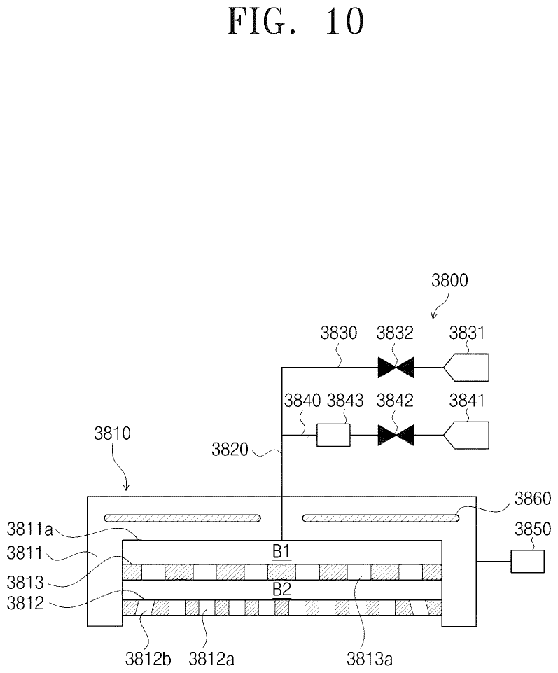

FIG. 10 is a schematic cross-sectional view of an example of the gas injection unit.

The gas injection unit 3800 includes a showerhead 3810, a main supply pipe 3820, a dehumidifying gas supply pipe 3830, a humidifying gas supply pipe 3840, a driver 3850, and a heater 3860.

The showerhead 3810 includes a body 3811, a first porous plate 3812, and a second porous plate 3813.

The body 3811 may be provided in a cylindrical shape with an open bottom. The first porous plate 3812 is coupled to the bottom end of the body. The second porous plate 3813 is provided on the inner of the body 3811. A gas introduction space B1 is formed between an upper surface 3811a of the body 3811 and the second porous plate 3813. A gas distribution space B2 is formed between the second porous plate 3813 and the first porous plate 3812.

In the first porous plate 3812, injection holes are formed. A first injection hole 3812a is formed in the center region of the first porous plate 3812. The first injection hole 3812a is provided to inject gas in a direction perpendicular to the substrate W. For example, the first injection hole 3812a may be formed in a direction parallel to the center axis of the showerhead 3810. A second injection hole 3812b is formed in an edge region of the first porous plate 3812. The second injection hole 3812b is provided to inject gas in a downwardly directed direction away from the substrate W. For example, the second injection hole 3812b is formed to slope downwardly in a direction away from the center axis of the showerhead 3810.

The second porous plate 3813 is disposed on top of the first porous plate 3812. The second porous plate 3813 is spaced apart from the first porous plate 3812. The second porous plate 3813 may be provided with the same size as the first porous plate 3812. Injection holes 3813a are formed in the second porous plate 3813. The opening area of a third injection hole 3813a formed in the second porous plate 3813 is provided to be larger than the opening area of the first injection hole 3812a and the second injection hole 3812b formed in the first porous plate 3812. For example, the first injection hole 3812a, the second injection hole 3812b, and the third injection hole 3813a are each provided in a circular shape, and the diameter of the third injection hole 3813a is provided larger than the diameters of the first injection hole 3812a and the second injection hole 3812b.

The showerhead 3810 is coupled to the main supply pipe 3820 that supplies the atmosphere gas. The main supply pipe 3820 supplies atmosphere gas to the gas introduction space B1. The atmosphere gas includes dehumidifying gas and humidifying gas. The dehumidifying gas flows through the dehumidifying gas supply pipe 3830 into the gas introduction space B1. The humidifying gas flows through the humidifying gas supply pipe 3840 into the gas introduction space B1.

The dehumidifying gas supply pipe 3830 connects the main supply pipe 3820 and a dehumidifying gas supply source 3831. A valve 3832 is installed in the dehumidifying gas supply pipe 3830. The dehumidifying gas supply source 3831 may store low humidity air, nitrogen, or inert gas.

The humidifying gas supply pipe 3840 connects the main supply pipe 3820 and a humidifying gas supply source 3841. A moisture generator 3843 and a valve 3842 are installed in the humidifying gas supply pipe 3840. The moisture generator 3843 may heat water stored within it, which may cause the gas supplied from the humidifying gas supply source 3841 to contain water vapor.

Further, when the dehumidifying gas and the humidifying gas are the same type of gas, the dehumidifying gas supply pipe 3830 and the humidifying gas supply pipe 3840 may be connected to the same gas supply source 3831 to receive gas.

The valves 3832 and 3842 installed in each of the dehumidifying gas supply pipe 3830 and the humidifying gas supply pipe 3840 may be open/close valves. Additionally, the dehumidifying gas supply pipe 3830 and the humidifying gas supply pipe 3840 may be equipped with flow regulating valves.

The driver 3850 moves the showerhead 3810 between the standby position h1 and the gas injection position h2. In one example, the standby position h1 is a position above the gas injection position h2.

The standby position h1 is a position at a height such that the showerhead 3810 does not interfere with the movement of the substrate W when the substrate W is received and transferred to the transfer plate 3600 from the outside.

The gas injection position h2 is a position where the showerhead 3810 is adjacent to the substrate W.

The showerhead 3810 may be provided with the heater 3860. In one example, the heater 3860 may be inserted into the showerhead 3810. Optionally, the heater 3860 may be positioned on a top surface of the showerhead 3810. The heater 3860 may heat the showerhead 3810 to provide the atmosphere gas with a high temperature. The heater 3860 may heat the showerhead 3810 to a temperature lower than the heat treatment temperature. In one example, the heater 3860 heats the dehumidifying gas to a temperature lower than the heating treatment temperature when providing dehumidifying gas from the showerhead 3810.

FIG. 10 is a front view schematically illustrating the liquid treating chamber of FIG. 3 or 4.

Referring to FIG. 10, the liquid treating chamber 380 has a housing 382, an outer cup 384, a support unit 386, and a liquid supply unit 387.

The housing 382 is provided in a rectangular cylindrical shape having an inner space. An opening 382a is formed in one side of the housing 382. The opening 382a functions as a passageway through which the substrate W enters and exits. A door (not illustrated) is installed in the opening 382a, and the door opens and closes the opening.

An inner space of the housing 382 is provided with the outer cup 384. The outer cup 384 has a treatment space with an open top.

A support unit 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The liquid supply unit 387 supplies the treatment solution onto the substrate W. When the liquid treating chamber 380 is provided in the applying block 300a, the treatment solution may be a liquid for forming a photoresist film, an anti-reflective film, or a protective film. When the liquid treating chamber 380 is provided in the developing block 300b, the treatment solution may be a developer liquid. The liquid supply unit 387 has a nozzle 387a, a nozzle support 387b, and a liquid supply source (not illustrated). The nozzle 387a discharges the treatment solution onto the substrate W. The nozzle 387a is supported on a nozzle support 387b. The nozzle support 387b moves the nozzle 387a between a process position and a standby position. In the process position, the nozzle 387a supplies the treatment solution to the substrate W placed on the support plate 386a, and after completing the supply of the treatment solution, the nozzle 387a waits in the standby position. In the standby position, the nozzle 387a waits at a groove port 388, the groove port 388 is located on the outside of the outer cup 384 within the housing 382.

A fan filter unit 383 that supplies downward airflow to the inner space is disposed on the upper wall of the housing 382 is disposed. The fan filter unit 383 includes a fan for introducing outside air into the inner space and a filter for filtering outside air.

The outer cup 384 has a bottom wall 384a, a sidewall 384b, and a top wall 384c. The inner of the outer cup 384 is provided as an inner space described above. The inner space H includes a treatment space at the top and an exhaust space at the bottom.

The bottom wall 384a is provided in a circular shape and has an opening in the center. The sidewall 384b extends upwardly from the outer end of the bottom wall 384a. The sidewall 384b is provided in a ring shape and is provided vertical to the bottom wall 384a. In one example, the sidewall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top end of the sidewall 384b toward the center axis of the outer cup 384.

The guide cup 385 is positioned on the inner side of the outer cup 384. The guide cup 385 has an inner wall 385a, an outer wall 385b, and a top wall 385c. The inner wall 385a has a through hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the sidewall 384b of the outer cup 384. The inner wall 385a is spaced upwardly from the bottom wall 384a of the outer cup 384. The top wall 385c connects the upper end of the outer wall 385b with the upper end of the inner wall 385a. The top wall 385c has a ring shape and is disposed to surround the support plate 386a. In one example, the top wall 385c has an upwardly convex shape.

The space below the support plate 386a in the treatment space may be provided as an exhaust space. In one example, the exhaust space may be defined by the guide cup 385. The space surrounded by the outer wall 385b, the top wall 385c, and the inner wall 385a of the guide cup 385 and/or the space below the space may be provided as the exhaust space.

The outer cup 384 may be provided with a gas-liquid separation plate 389. A gas-liquid separation plate 389 may be provided to extend upwardly from the bottom wall 384a of the outer cup 384. The gas-liquid separation plate 1230 may be provided in a ring shape. The gas-liquid separation plate 389 may be positioned between the sidewall 384b of the outer cup 384 and the outer wall 385b of the guide cup 385 when viewed from above. The top end of the gas-liquid separation plate 389 may be positioned lower than the bottom end of the outer wall 385b of the guide cup 385.

The bottom wall 384a of the outer cup 384 is connected to an outlet pipe 381a for discharging the treatment liquid and an exhaust pipe 381b. The outlet pipe 381a may be connected to the outer cup 384 from the outer side of the gas-liquid separation plate 389. The exhaust pipe 381b may be connected to the outer cup 384 from an inner side of the gas-liquid separation plate 389.

The interface module 500 connects the treating module 300 with an external exposure device 700. The interface module 500 includes an interface frame 501, a buffer unit 510, a cooling unit 520, a transfer mechanism 530, an interface robot 540, and an additional process chamber 560.

A fan filter unit for forming a descending airflow therein may be provided at an upper end of the interface frame 501. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W being transferred between the treating module 300, the cooling unit 520, the additional process chamber 560, and the exposure device 700 may temporarily reside in the buffer unit 510. The cooling unit 520 may be provided only at a height corresponding to the application block 300a between the application block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided relative to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface robot 540 includes a hand 542 on which the substrate W is placed, and the hand 542 may be provided to be movable forwardly and backwardly, rotatable about the third direction 16, and movable along the third direction 16.

The additional process chamber 560 may perform a predetermined additional process before the substrate W processed in the applying block 300a is loaded to the exposure device 700. Optionally, the additional process chamber 560 may perform a predetermined additional process before the substrate W processed in the exposure device 700 is loaded to the developing block 300b. In one example, the additional process may be an edge exposure process for exposing an edge region of the substrate W, or a top surface cleaning process for cleaning the top surface of the substrate W, or a bottom surface cleaning process for cleaning the bottom surface of the substrate W, or an inspection process for performing a predetermined inspection on the substrate W. A plurality of additional process chambers 560 may be provided, which may be stacked on top of each other.

Next, a method of heat treating the substrate W in the heat treating chamber will be described in detail.

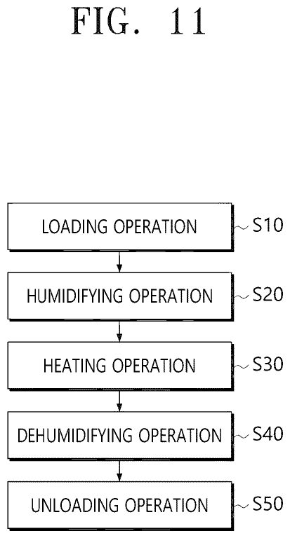

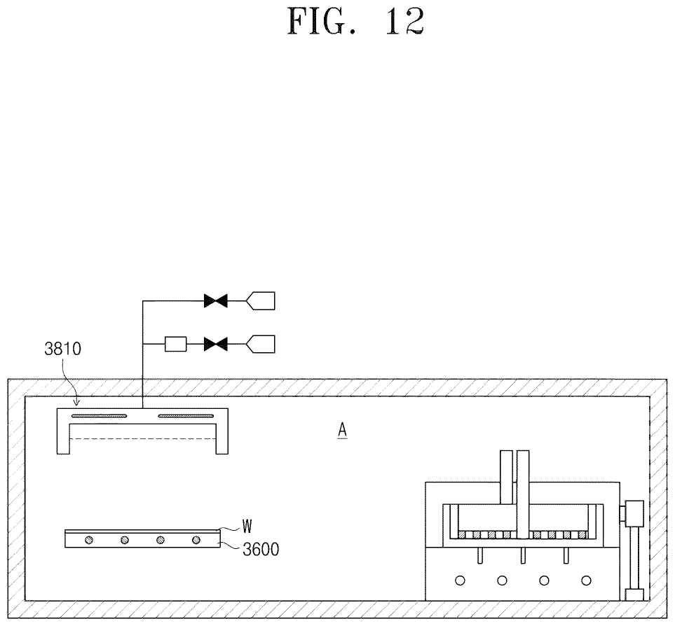

FIG. 11 is a flowchart sequentially illustrating a method of heat treating the substrate W, and FIGS. 12 to 16 are diagrams sequentially illustrating the process of heat treating the substrate W, respectively. The substrate treating method may be performed by controlling the configurations provided to the heat treating chamber by the controller 3900. For example, the configuration provided in the heat treating chamber may be a heater, respective valves, respective drivers, heaters 3860, and the like. Further, the controller may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treatment recipe, for executing the process in each component according to various data and processing conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

In the following, the present invention will be described based on the case where the photoresist film is a metal-containing film and the heat treatment process is a bake process after an exposure as an example.

According to the method of heat treating the substrate W, a loading operation S10, a humidifying operation S20, a heating operation S30, a dehumidifying operation S40, and an unloading operation S50 are performed sequentially.

As illustrated in FIG. 12, in the loading operation S10, the showerhead 3810 is positioned in the standby position h1. The transfer plate 3600 is positioned in an outer position L1.

The substrate W is loaded into the inner space A of the heat treating chamber. The transfer robot 351 loads the substrate W into the inner space A of the housing 3200. In the position where the hand 352 of the transfer robot 351 and the transfer plate 3600 are aligned in an up-down direction, the hand 352 is moved in a direction lower than the transfer plate 3600. Thereby, the substrate W is transferred from the hand 352 to the transfer plate 3600.

After the substrate W is handed over to the transfer plate 3600, the humidifying operation S20 is performed.

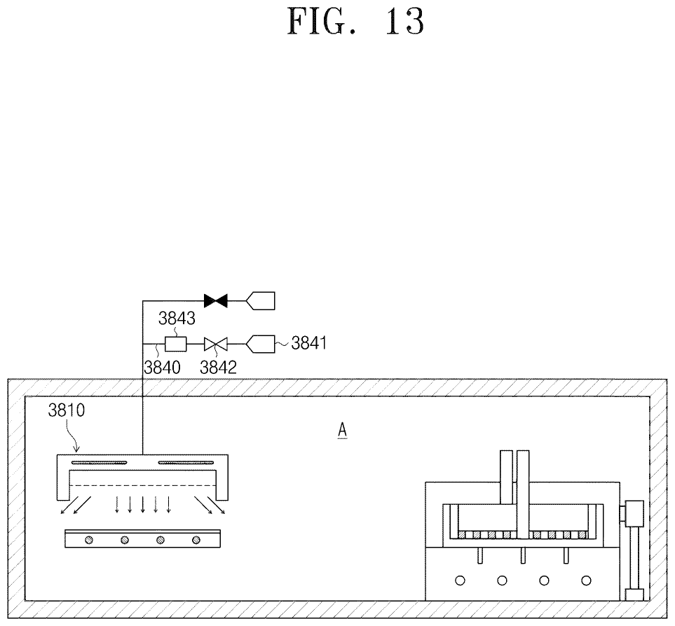

As illustrated in FIG. 13, the humidifying operation S20 is performed while the substrate W is supported on the transfer plate 3600. During the humidifying operation S20, the transfer plate 3600 waits for a predetermined time in the outer position L1. The showerhead 3810 is lowered from the standby position h1 to the gas injection position h2. While the showerhead 3810 is in the gas injection position h2, humidifying gas is injected from the showerhead 3810 onto the substrate W. After a preset time elapses, the humidifying operation S20 is completed.

The humidifying operation is performed to improve the reactivity of the metal-containing resist by moisture even before the substrate is loaded into the heating unit. Furthermore, the amount of dehumidifying gas may be reduced by supplying humidifying gas only to the substrate region disposed at the outer position and/or a region adjacent to the substrate region.

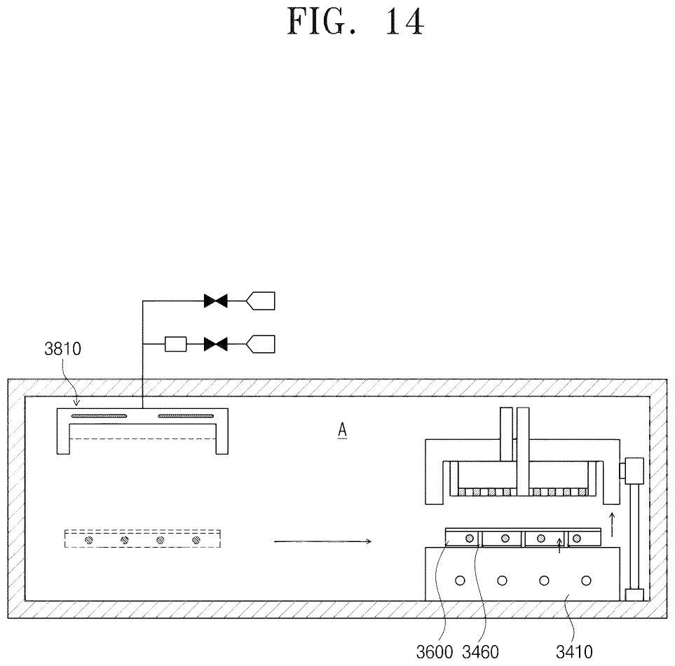

The substrate W is then transferred to the treatment space C2 of the heating unit 3400, as illustrated in FIG. 14. The showerhead 3810 is raised to the standby position h1, and the cover 3420 of the heating unit 3400 is raised. The transfer plate 3600 moves from the outer position L1 to the inner position L2. The substrate W is transferred onto the heating plate 3410 by the above-described change of position between the lift pin 3460 and the transfer plate 3600.

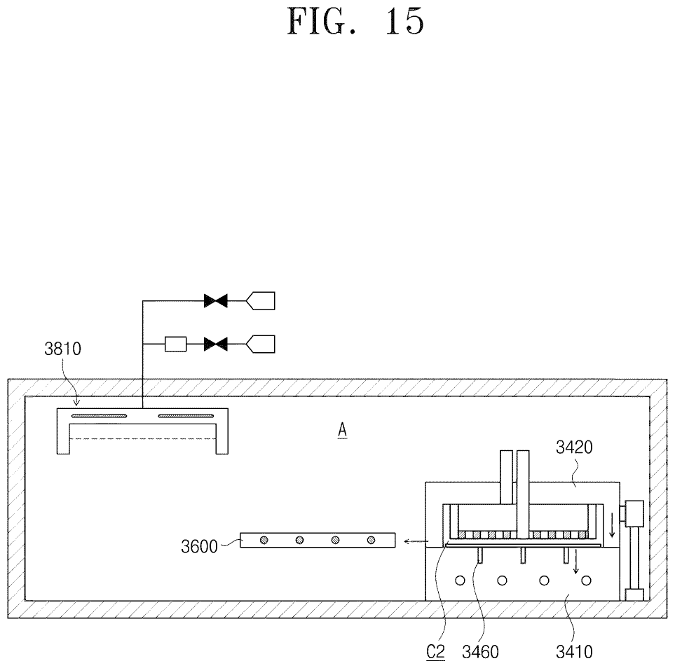

As illustrated in FIG. 15, in the heating operation S30, the substrate W on the heating plate 3410 is heated to a predetermined temperature. The transfer plate 3600 moves from the outer position L1 to the inner position L2. At the inner position L2, the substrate W is transferred to the lift pin 3460, which has been previously raised and is waiting. The lift pin 3460 is then lowered to place the substrate W on the heating plate 3410. The transfer plate 3600 is moved outwardly of the heating unit 3400. The cover 3420 is lowered, and the cover 3420 and the heating plate 3410 are brought into contact to form the treatment space C2. The substrate W is heated by the heating plate 3410. While the substrate W is being heated, humidifying gas is supplied to the treatment space C2 from the humidifying gas supply source 3442a. While the first gas is supplied, the atmosphere in the treatment space C2 is exhausted to the outside through the exhaust pipe 3510. After the heating process proceeds for a set period of time, a substitution process is performed. In the substitution process, the supply of humidifying gas from the humidifying gas supply source 3442a is stopped and dehumidifying gas is supplied from the dehumidifying gas supply source 3443a is supplied to the treatment space C2. While the humidifying gas is being supplied, the atmosphere in the treatment space C2 is exhausted to the outside through the exhaust pipe 3510.

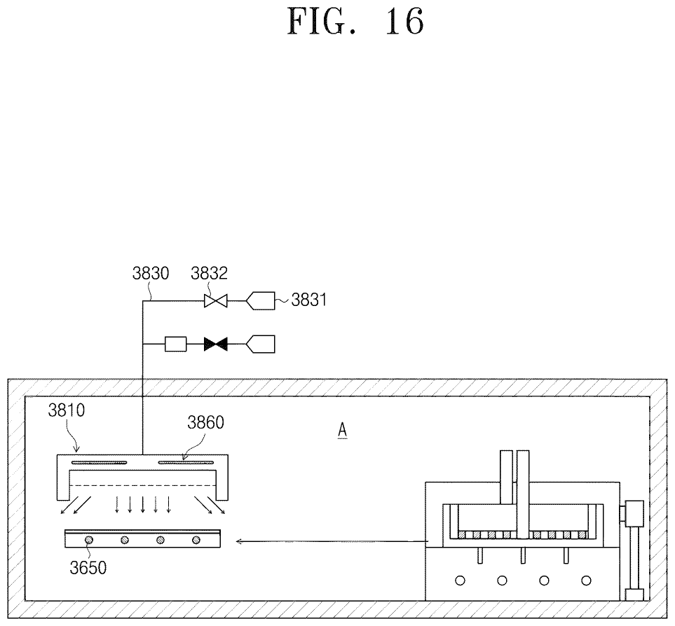

When the substitution process is complete, the cover 3420 is raised as illustrated in FIG. 16. The transfer plate 3600 is moved to the inner position L1 and the substrate W is transferred to the transfer plate 3600 by the lift pin 3460. The transfer plate 3600 is then moved from the inner position L2 to the outer position L1. The first gas is supplied to heat the substrate W so that the reactivity of the metal-containing resist may be improved.

The dehumidifying operation S40 is then performed.

As illustrated in FIG. 16, the dehumidifying operation S40 is performed in the state where the substrate W is supported on the transfer plate 3600. During the dehumidifying operation S40, the transfer plate 3600 waits for a preset time in the outer position L1. The showerhead 3810 is lowered from the standby position h1 to the gas injection position h2. The heater 3860 heats the showerhead 3810 to a preset temperature. When the showerhead 3810 is positioned in the gas injection position h2, dehumidifying gas is injected from the showerhead 3810 onto the substrate W. After a preset time elapses, the dehumidifying operation S40 is completed.

During the dehumidifying operation S40, the substrate W is cooled by the cooling member 3520 provided on the transfer plate 3600.

Even when the substrate W is unloaded from the heating unit 3400 at a high temperature state without the moisture being completely removed by the dehumidifying gas within the heating unit 3400, the substrate W may be maintained at a low humidity by further the dehumidifying operation, thereby removing the moisture on the substrate W.

Furthermore, the amount of dehumidifying gas may be reduced by supplying dehumidifying gas only to the region of the substrate W disposed in the outer position L1 and/or the region adjacent thereto.

Furthermore, even though the substrate W is removed from the heating unit 3400 in a high temperature state, the substrate W may be reliably cooled by supplying dehumidifying gas having a lower temperature than the substrate W to the substrate.

The unloading operation S50 is then performed. The showerhead 3810 rises from the gas injection position h2 to the standby position h1.

The hand of the transfer robot 351 is loaded into the inner space A of the housing 3200. As the hand is moved in the upward direction, the substrate W placed on the transfer plate 3600 is taken over by the hand. The hand moves to the transfer chamber 350 to unload the substrate W from the heat treating chamber.

In the example described above, the showerhead 3810 is described as moving from the gas injection position to the standby position h1 while the transfer plate 3600 is being moved to the inner position L2 and the outer position L1. However, when the showerhead 3810 is positioned in the gas injection position and the transfer plate 3600 does not interfere with the showerhead 3810 as the transfer plate 3600 moves from the outer position L1 to the inner position L2, the showerhead 3810 may remain positioned in the gas injection position.

In the following, various modified exemplary embodiments of the heat treating chamber 360 will be described.

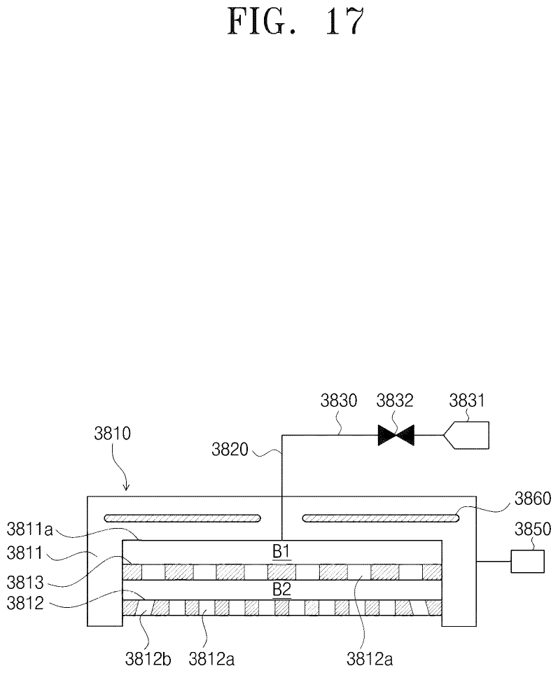

In the exemplary embodiments described above, the atmosphere gas unit 3800 is described as having both the humidifying gas supply pipe 3840 and the dehumidifying gas supply pipe 3830. In contrast to this, however, the atmosphere gas unit 3800 may be provided with only the dehumidifying gas supply pipe 3830, as illustrated in FIG. 17, and the heating operation may be performed without the humidifying operation after the loading operation.

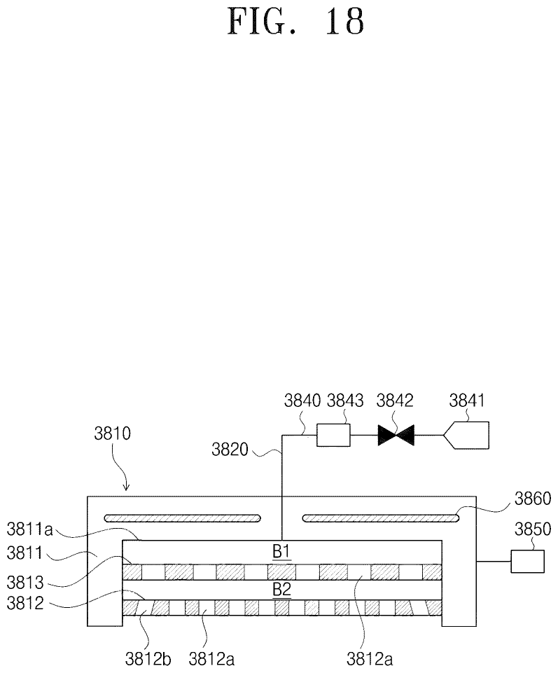

Optionally, the atmosphere gas unit 3800 may be provided with only the humidifying gas supply pipe 3840, as illustrated in FIG. 18, and the unloading process may be performed without the dehumidifying process after the heating process. While the transfer plate 3600 is in the outer position L1, only the dehumidifying process may be performed without the humidifying process described above.

In the exemplary embodiments described above, the showerhead 3810 is described as having both the first porous plate 3812 and the second porous plate 3813. In contrast, however, the showerhead may be provided with only one porous plate.

Furthermore, in the exemplary embodiment described above, it has been described that in the edge region of the first porous plate 3812, the second injection hole 3812b is provided to inject gas in a downwardly directed direction away from the substrate W. However, alternatively, the second injection hole 3812b may be provided to inject gas in the same direction perpendicular to the substrate W as the first injection hole 3812a.

Furthermore, in the exemplary embodiments described above, it has been described that the atmosphere gas unit 3800 performs the humidifying operation before the heating treatment and the dehumidifying operation is performed after the heating treatment. In contrast to this, however, only one of the humidifying operation S20 and the dehumidifying operation S40 may be performed.

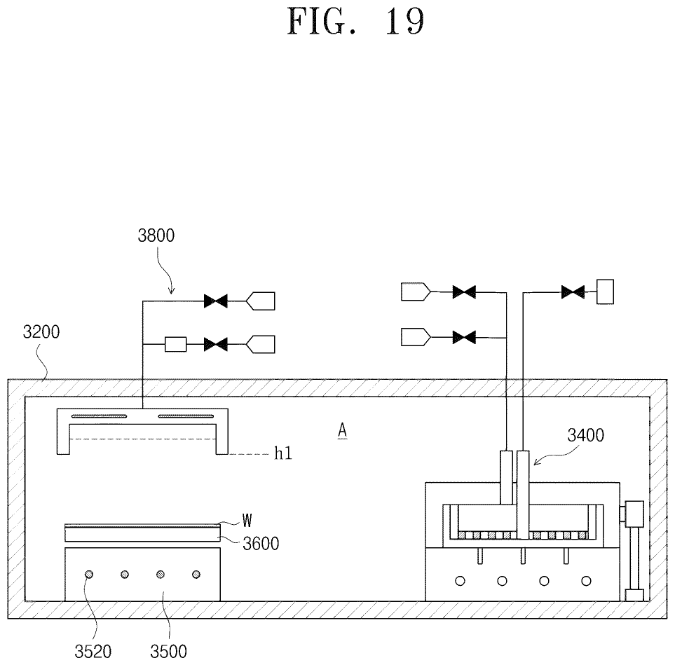

Further, the present invention has been described that the cooling member 3650 in the heat treating chamber 360 is provided to the transfer plate 3600. However, alternatively, a cooling unit 3500 may be further disposed in the heat treating chamber 360, as illustrated in FIG. 19, and the cooling member 3520 may be provided in the cooling unit 3500. The substrate W may be placed directly on the cooling unit 3500 and cooled, or the substrate may be cooled by placing the transfer plate by which the substrate is supported on the cooling unit. In this case, the outer position L1 may be the position where the cooling unit 3500 is provided.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the disclosure, and all such modifications that would be obvious to one of ordinary skill in the art are intended to be included within the scope of the accompanying claims.

What is claimed is:

1. An apparatus for treating a substrate, the apparatus comprising:
a housing providing an inner space;
a heating unit provided in the inner space, and providing a treatment space in which a heating process of the substrate is performed;
a transfer plate positioned within the inner space, and movable between an inner position for loading the substrate into the treatment space or for unloading the substrate from the treatment space and an outer position provided outside the heating unit; and
a gas injection unit positioned within the inner space, and for injecting atmosphere gas toward the substrate at the outer position.

2. The apparatus of claim 1, wherein the gas injection unit includes a showerhead including a plurality of holes formed to discharge the atmosphere gas in a downward direction.

3. The apparatus of claim 2, wherein the atmosphere gas includes dehumidifying gas, and
the gas injection unit includes a dehumidifying gas supply pipe that supplies the dehumidifying gas to the showerhead.

4. The apparatus of claim 3, wherein the gas injection unit further includes a heater provided in the showerhead.

5. The apparatus of claim 2, wherein the atmosphere gas includes humidifying gas, and
the gas injection unit includes a humidifying gas supply pipe supplying the humidifying gas to the showerhead.

6. The apparatus of claim 5, wherein the gas injection unit further includes a humidity regulating unit for regulating humidity of the humidifying gas.

7. The apparatus of claim 3, further comprising:
a controller for controlling the gas injection unit,
wherein the controller controls the gas injection unit so that the gas injection unit injects the dehumidifying gas toward the substrate while the substrate is waiting at the outer position, after the substrate is unloaded from the heating unit.

8. The apparatus of claim 5, further comprising:
a controller for controlling the gas injection unit,
wherein the controller controls the gas injection unit so that the gas injection unit injects the humidifying gas toward the substrate while the substrate is waiting at the outer position, before the substrate is loaded into the heating unit.

9. The apparatus of claim 2, wherein the showerhead includes a first porous plate and a second porous plate,
the second porous plate is positioned above the first porous plate within the showerhead, and
an opening area of a hole formed in the second porous plate is provided to be larger than an opening area of a hole formed in the first porous plate.

10. The apparatus of claim 2, wherein the showerhead has a plurality of first holes and a plurality of second holes,
the plurality of first holes is formed in a center region of the showerhead to provide gas in a direction perpendicular to the substrate, and
the plurality of second holes is formed in an edge region of the showerhead to supply gas in a downwardly sloping direction away from the substrate.

11. The apparatus of claim 1, wherein the outer position is the position where the transfer plate receives the substrate from a transfer member located on the outside of the housing.

12. The apparatus of claim 2, wherein the gas injection unit further includes a driver for raising and lowering the showerhead between a standby position and a second height lower than the standby position.

13. The apparatus of claim 1, wherein the transfer plate includes:
a transfer plate on which the substrate is placed; and
a cooling member provided at the transfer plate to cool the substrate.

14. An apparatus for treating a substrate, the apparatus comprising:
a housing providing an inner space;
a heating unit provided in the inner space, and providing a treatment space in which a bake treating process of the substrate is performed;
a transfer plate positioned within the inner space, and movable between an outer position provided on an exterior side of the heating unit and an inner position for loading the substrate into the treatment space or for unloading the substrate from the treatment space within the inner space; and
a gas injection unit positioned above the transfer plate located at the outer position to be opposite the transfer plate, and for injecting atmosphere gas toward a substrate supported on the transfer plate,
wherein the gas injection unit includes:
a showerhead;
a dehumidifying gas supply line for supplying dehumidifying gas to the showerhead;
a humidifying gas supply line for supplying humidifying gas to the showerhead; and
a driver for raising and lowering the showerhead between a standby position and a second height lower than the standby position, and
the outer position is a position where the transfer plate receives a substrate from a transfer member located on the outside of the housing.

15. The apparatus of claim 14, further comprising:
a controller for controlling the gas injection unit,
wherein the controller controls the gas injection unit so that the gas injection unit injects humidifying gas toward the substrate while the substrate is supported on the transfer plate that waits at the outer position, before the substrate is loaded into the heating unit, and so that the gas injection unit injects dehumidifying gas toward the substrate while the substrate is supported on the transfer plate that waits at the outer position, after the substrate is unloaded from the heating unit.
